(19) United States
(12) Patent Application Publication
(10) Pub. No.: US 2025/0151412 A1
(43) Pub. Date: May 8, 2025

(54) SEMICONDUCTOR INTEGRATED CIRCUIT DEVICE

(71) Applicant: Socionext Inc., Kanagawa (JP)

(72) Inventor: Hidetoshi TANAKA, Yokohama-shi (JP)

(21) Appl. No.: 19/018,857

(22) Filed: Jan. 13, 2025

Related U.S. Application Data
(63) Continuation of application No. PCT/JP2022/029961, filed on Aug. 4, 2022.

(51) Int. Cl. H10D 89/60; H01L 23/522; H10D 1/47

(52) U.S. Cl. CPC H10D 89/911; H01L 23/5228; H10D 89/921; H10D 1/47

(57) ABSTRACT

An IO cell includes an output circuit having a protective resistance. The protective resistance is constituted by a plurality of resistor elements formed in a first interconnect layer that is formed in the back end of line (BEOL). In an interconnect layer located below the first interconnect layer, interconnects that are each a power supply line or a signal line extend in the X direction and are adjacent to each other in the Y direction. The interconnects do not overlap any of the resistor elements in planar view, and at least one resistor element is placed between the interconnects.

### CROSS-REFERENCE TO RELATED APPLICATIONS

This is a continuation of International Application No. PCT/JP2022/029961 filed on Aug. 4, 2022. The entire disclosure of this application is incorporated by reference herein.

### BACKGROUND

The present disclosure relates to a semiconductor integrated circuit device having a core region and an IO region placed on a chip, and more particularly to a layout structure of IO cells arranged in the IO region.

In a semiconductor integrated circuit, input/output (IO) cells are arranged around the core region, and input/output of signals from/to the outside of the semiconductor integrated circuit device, as well as supply of power, are performed through the IO cells.

In the recent miniaturization processes, it is a widespread practice to constitute the gate of a transistor by a high-k gate insulating film and a metal gate. Because of this, it has become difficult to use a non-silicided polysilicon resistance formed in the front end of line (FEOL: substrate process) as a resistor element. Presently, a resistor element made of a metal compound, such as titanium nitride, formed between metal interconnect layers in the back end of line (BEOL: interconnect process) has come into use.

United States Patent Publication No. 2019/0304905 discloses a semiconductor integrated circuit device in which a resistor element formed between metal interconnect layers in the BEOL is placed above a diode element as an electrostatic discharge (ESD) protection element, for example.

When resistor elements are formed in the BEOL, they are to be provided in an interconnect layer. This increases the parasitic capacitance between the resistor elements and other interconnects in interconnect layers located above and below the resistor elements. In the miniaturization processes, in which semiconductor integrated circuits are becoming increasingly faster, this parasitic capacitance may block speedup of signals. It is therefore required to reduce the parasitic capacitance related to resistor elements provided in an interconnect layer.

An objective of the present disclosure is providing a configuration of a semiconductor integrated circuit device using resistor elements formed in the BEOL in which the parasitic capacitance related to the resistor elements can be reduced.

### SUMMARY

According to the first mode of the disclosure, in a semiconductor integrated circuit device including a plurality of IO cells arranged in a first direction, at least one of the plurality of IO cells includes an output circuit, the output circuit includes an external output terminal, and a protective resistance constituted by a plurality of resistor elements formed in a first interconnect layer, the first interconnect layer being formed in an interconnect process (back end of line (BEOL)), one of ends of the protective resistance being connected to the external output terminal, the plurality of resistor elements of the protective resistance extend in the first direction and are connected to interconnects formed in a second interconnect layer through vias, in a third interconnect layer located below the first interconnect layer, first and second interconnects that are each a power supply line or a signal line extend in the first direction and are placed adjacent to each other in a second direction perpendicular to the first direction, and the first and second interconnects are placed at positions having no overlap with any of the plurality of resistor elements in planar view, and at least one of the plurality of resistor elements is placed between the first interconnect and the second interconnect.

According to the above mode, at least one of the plurality of IO cells arranged in the first direction includes an output circuit. A protective resistance of the output circuit is constituted by a plurality of resistor elements extending in the first direction formed in a first interconnect layer that is formed in the BEOL. In a third interconnect layer located below the first interconnect layer, first and second interconnects that are each a power supply line or a signal line extend in the first direction and are placed adjacent to each other in the second direction. The first and second interconnects are placed at positions having no overlap with any of the plurality of resistor elements in planar view, and resistor elements are placed between the first and second interconnects. With this, since the first and second interconnects in the interconnect layer located below the resistor elements are placed at positions avoiding the resistor elements, the parasitic capacitance of the interconnects with the resistor elements is kept small. Therefore, the parasitic capacitance related to the resistor elements can be reduced.

According to the present disclosure, in a semiconductor integrated circuit device using resistor elements formed in the BEOL, parasitic capacitance related to the resistor elements can be reduced.

### BRIEF DESCRIPTION OF THE DRAWINGS

FIG. 1 is a plan view schematically showing the entire configuration of a semiconductor integrated circuit device according to an embodiment.

FIG. 2 is a circuit configuration diagram of an output circuit according to the first embodiment.

FIG. 3 shows an overview example of an IO cell layout in the first embodiment.

FIG. 4 is a plan view showing details of the IO cell layout of FIG. 3

FIG. 5 is a cross-sectional view showing details of the IO cell layout of FIG. 3

FIG. 6 is a plan view showing details of the IO cell layout of FIG. 3

FIG. 7 is a circuit configuration diagram of an output circuit according to the second embodiment.

FIG. 8 shows an overview example of an IO cell layout in the second embodiment.

FIG. 9 is a plan view showing details of the IO cell layout of FIG. 8.

FIG. 10 shows an overview example of an IO cell layout in an alteration of the second embodiment.

### DETAILED DESCRIPTION

Embodiments of the present disclosure will be described hereinafter with reference to the accompanying drawings. In the following description, “VDDIO” and “VSS” are assumed to indicate power supply voltages or power supplies themselves. It is also assumed that transistors are formed on a P-substrate and an N-well. Note however that transistors may be formed on a P-well and an N-substrate.

### First Embodiment

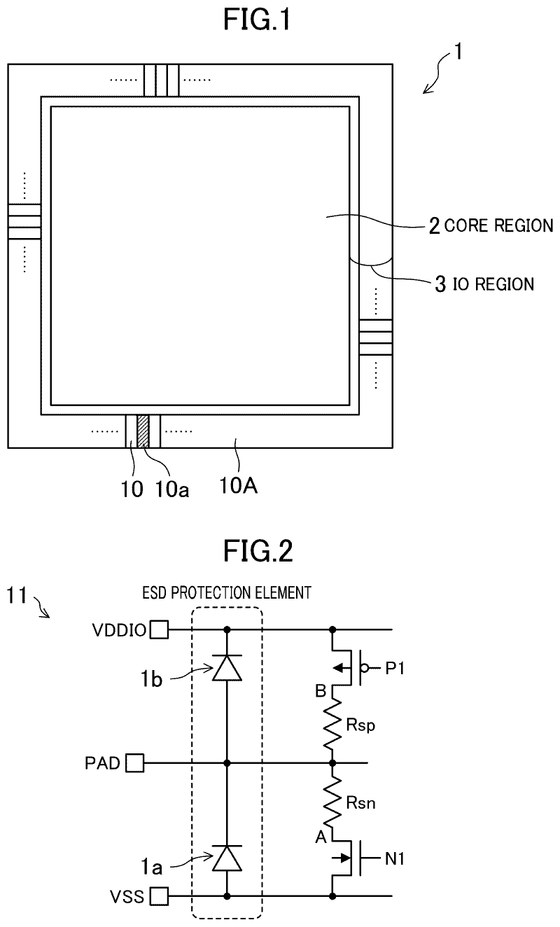

FIG. 1 is a plan view schematically showing the entire configuration of a semiconductor integrated circuit device according to an embodiment. The semiconductor integrated circuit device 1 shown in FIG. 1 includes: a core region 2 in which internal core circuits are formed; and an IO region 3 provided between the core region 2 and the chip edges, in which interface circuits (IO circuits) are formed. An IO cell row 10A is provided in the IO region 3 to encircle the peripheral portion of the semiconductor integrated circuit device 1. Although illustration is simplified in FIG. 1, a plurality of IO cells 10 constituting interface circuits are arranged in line in the IO cell row 10A. Also, although illustration is omitted in FIG. 1, a plurality of external connection pads are placed in the semiconductor integrated circuit device 1. Note that the IO cell row 10A may be provided partly in the peripheral portion of the semiconductor integrated circuit device 1.

The IO cells 10 include signal IO cells and power IO cells. The signal IO cells include circuits required to exchange signals with the outside of the semiconductor integrated circuit device 1 or with the core region 2, such as a level shifter circuit, an output buffer circuit, and a circuit for ESD protection. The power IO cells, which supply power fed to the external connection pads to the inside of the semiconductor integrated circuit device 1, include a circuit for ESD protection, for example.

FIG. 2 is a circuit configuration diagram of an output circuit 11 included in the IO cells 10. Note that, although an actual output circuit includes circuit elements other than those shown in FIG. 2, such elements are omitted in FIG. 2.

The output circuit 11 shown in FIG. 2 includes an external output terminal PAD, output transistors P1 and N1, electrostatic discharge (ESD) protection diodes 1a and 1b, and protective resistances Rsn and Rsp. The output transistor P1 is a p-type transistor and the output transistor N1 is an n-type transistor.

The output transistors P1 and N1 output signals to the external output terminal PAD according to signals received at their gates. The output transistor P1 is connected to VDDIO at its source and to the external output terminal PAD at its drain through the protective resistance Rsp. The output transistor N1 is connected to VSS at its source and to the external output terminal PAD at its drain through the protective resistance Rsn. In this embodiment, the protective resistances Rsp and Rsn are each constituted by a plurality of resistor elements formed in an interconnect layer that is formed in the back end of line (BEOL: interconnect process). Note that the node between the output transistor N1 and the protective resistance Rsn is herein called node A and the node between the output transistor P1 and the protective resistance Rsp is called node B.

The ESD protection diode 1a is provided between VSS and the external output terminal PAD, with its anode connected to VSS and its cathode connected to the external output terminal PAD. The ESD protection diode 1b is provided between VDDIO and the external output terminal PAD, with its anode connected to the external output terminal PAD and its cathode connected to VDDIO. When high-voltage noise is input into the external output terminal PAD, a current flows to VDDIO and VSS through the ESD protection diodes 1a and 1b, whereby the output transistors P1 and N1 are protected.

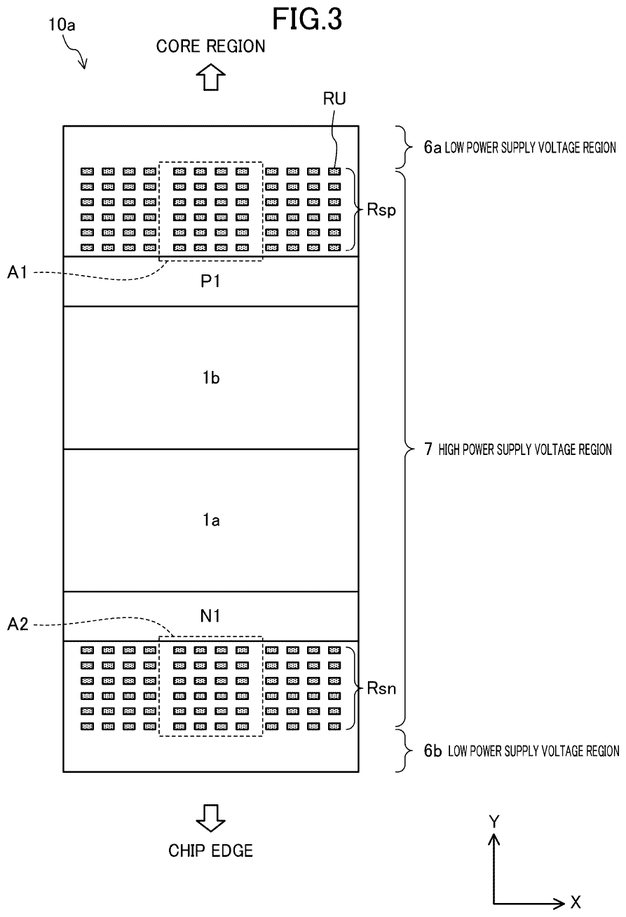

FIG. 3 shows an overview example of the IO cell layout. The layout of FIG. 3 corresponds to an IO cell 10a, one of the IO cells 10 arranged along the lower edge of the semiconductor integrated circuit device 1 in FIG. 1. Note herein that the X direction (corresponding to the first direction) is the direction along an outer edge of the semiconductor integrated circuit device 1, along which a plurality of IO cells 10 are arranged, and the Y direction (corresponding to the second direction) is the direction perpendicular to the X direction.

An IO cell generally includes: a high power supply voltage region including a circuit for ESD protection and an output buffer for outputting a signal to the outside of the semiconductor integrated circuit device; and a low power supply voltage region including a circuit for inputting/outputting a signal into/from the inside of the semiconductor integrated circuit device. The IO cell 10a of FIG. 3 has two low power supply voltage regions 6a and 6b and a high power supply voltage region 7 separated from one another in the Y direction. The low power supply voltage region 6a is located closer to the core region 2 and the low power supply voltage region 6b is located closer to the chip edge. The high power supply voltage region 7 is located between the low power supply voltage region 6a and the low power supply voltage region 6b.

The low power supply voltage region 6a, located near the output transistor P1, includes a circuit that generates a signal input into the gate of the output transistor P1, for example. The low power supply voltage region 6b, located near the output transistor N1, includes a circuit that generates a signal input into the gate of the output transistor N1, for example.

The IO cell 10a shown in FIG. 3 constitutes the output circuit 11 of FIG. 2. In the high power supply voltage region 7, the output transistor N1, the ESD protection diode 1a, the ESD protection diode 1b, and the output transistor P1 are formed in this order from the chip edge. Resistor elements RU are arranged in an array in the X and Y directions above sectors of the high power supply voltage region 7 other than the sectors where the output transistor N1, the ESD protection diode 1a, the ESD protection diode 1b, and the output transistor P1 are placed. The resistor elements RU placed above the sector near the output transistor P1 are mutually connected to constitute the protective resistance Rsp. The resistor elements RU placed above the sector near the output transistor N1 are mutually connected to constitute the protective resistance Rsn.

The connecting style of the resistor elements RU may be serial connection, parallel connection, or a combination of serial connection and parallel connection. Also, some of the resistor elements RU constituting the protective resistance Rsp may lie over the low power supply voltage region 6a, and some of the resistor elements RU constituting the protective resistance Rsn may lie over the low power supply voltage region 6b.

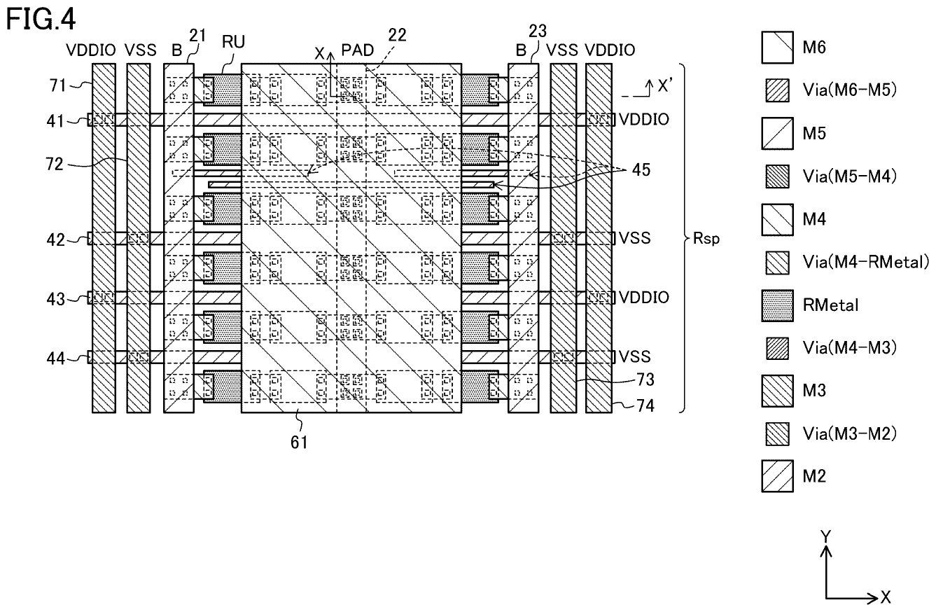

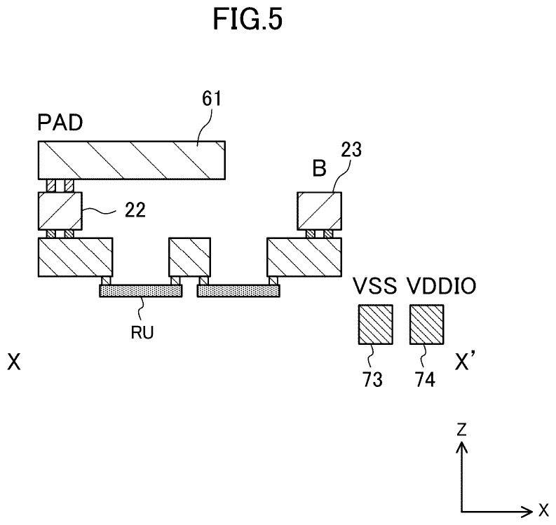

FIGS. 4 and 5 are views showing details of the layout of the IO cell, in which FIG. 4 is a plan view showing the structure of M2 to M6 interconnect layers in part Al in FIG. 3, and FIG. 5 is a cross-sectional view taken along line X-X′ in FIG. 4.

An RMetal interconnect layer, formed between the M4 interconnect layer and the M3 interconnect layer, is a layer for forming the resistor elements RU. The RMetal interconnect layer is formed in the BEOL (interconnect process). The resistor elements RU formed in the

RMetal interconnect layer are connected to interconnects in the M4 interconnect layer through vias.

In the M6 interconnect layer, an M6 interconnect 61 extending in the X and Y directions is formed. The M6 interconnect 61 corresponds to the external output terminal PAD and is connected to an IO pad not shown. In the M5 interconnect layer, M5 interconnects 21, 22, and 23 extending in the Y direction are formed. The M5 interconnect 22 is connected to the M6 interconnect 61 through a via and corresponds to the external output terminal PAD. The M5 interconnects 21 and 23 correspond to the node B.

The resistor elements RU are formed in the RMetal interconnect layer. Each two of the resistor elements RU are connected in series between the external output terminal PAD and the node B. That is, as is found from FIGS. 4 and 5, the resistor elements RU are connected between the external output terminal PAD and the node B through a route of M6 interconnect 61 (PAD)→via (M6-M5)→M5 interconnect 22→via (M5-M4)→M4 interconnect→via (M4-RMetal)→resistor element RU→via (M4-RMetal)→M4 interconnect→via (M4-RMetal)→resistor element RU→via (M4-RMetal)→M4 interconnect→via (M5-M4)→M5 interconnect 23 (node B). Similarly, each two of the resistor elements RU are connected in series between the M6 interconnect 61 (PAD) and the M5 interconnect 21 (node B). The protective resistance Rsp is constituted by a plurality of such resistor elements RU.

The reason why each two of the resistor elements RU are connected in series between the external output terminal PAD and the node B is to dissipate heat efficiently. That is, with the structure shown in FIGS. 4 and 5, heat generated in a resistor element RU can be efficiently dissipated from the M4 interconnects connected at both ends of the resistor element RU. Note that three or more resistor elements RU may be connected in series between the external output terminal PAD and the node B, or one resistor element RU may be connected between the external output terminal PAD and the node B.

In the M3 interconnect layer, M3 interconnects 71 and 72 extending in the Y direction are placed on the left side of the M5 interconnect 21 in the figure, and M3 interconnects 73 and 74 extending in the Y direction are placed on the right side of the M5 interconnect 23 in the figure. The M3 interconnects 71 and 74 are power supply lines supplying VDDIO, and the M3 interconnects 72 and 73 are power supply lines supplying VSS.

In the M2 interconnect layer, M2 interconnects 41, 42, 43, and 44 extending in the X direction are placed to reinforce the power supply. The M2 interconnects 41 and 43 are connected to the M3 interconnects 71 and 74 through vias, and the M2 interconnects 42 and 44 are connected to the M3 interconnects 72 and 73 through vias. The M2 interconnects 41, 42, 43, and 44 may be omitted since they are interconnects for reinforcing the power supply. In the M2 interconnect layer, also, M2 interconnects 45 that are signal lines extending in the X direction are placed. The signal lines 45 are connected to transistors and the like not shown. Note that FIG. 4 shows a mere example of placement of the power supply lines and the signal lines in the M2 interconnect layer and the placement is not limited to this.

None of the M2 interconnects 41, 42, 43, 44, and 45 that are power supply lines or signal lines in the M2 interconnect layer overlap any of the resistor elements RU in planar view. For example, the M2 interconnects 42 and 43 that are power supply lines are placed adjacent to each other in the Y direction. The M2 interconnects 42 and 43 do not overlap any resistor elements RU in planar view, and resistor elements RU are placed between these interconnects. That is, the M2 interconnects 42 and 43 are placed to sandwich the resistor elements RU in planar view. Also, the M2 interconnect 41 that is a power supply line and the M2 interconnects 45 that are signal lines are placed adjacent to each other in the Y direction. The M2 interconnects 41 and 45 do not overlap any resistor elements RU in planar view, and resistor elements RU are placed between these interconnects. In other words, the power supply lines and the signal lines in the M2 interconnect layer are placed at positions avoiding the resistor elements RU in planar view. With this, the parasitic capacitance between the interconnects and the resistor elements RU is reduced.

Also, none of the M5 interconnects 21, 22, and 23 in the M5 interconnect layer overlap any resistor elements RU in planar view. For example, the M5 interconnect 21 corresponding to the node B and the M5 interconnect 22 corresponding to the external output terminal PAD are placed adjacent to each other in the X direction. The M5 interconnects 21 and 22 do not overlap any resistor elements RU in planar view, and resistor elements RU are placed between these interconnects. That is, the M5 interconnects 21 and 22 are placed to sandwich the resistor elements RU in planar view. With this, the parasitic capacitance related to the resistor elements RU is reduced.

Note that the M5 interconnect 22 corresponding to the external output terminal PAD is allowed to overlap resistor elements RU in planar view.

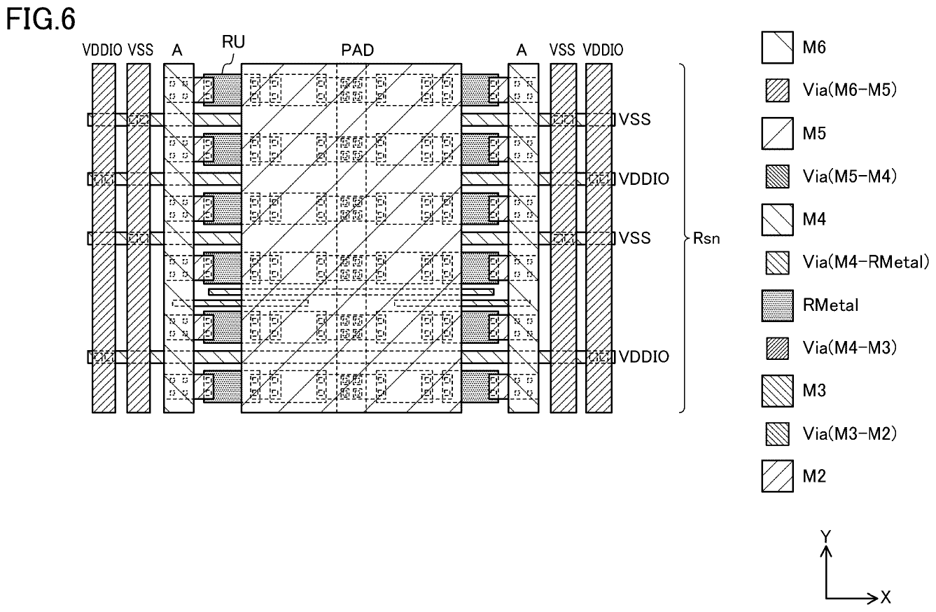

FIG. 6 is a plan view showing the structure of the M2 to M6 interconnect layers in part A2 in FIG. 3. The layout of FIG. 6 corresponds to the one obtained by inverting the layout of FIG. 4 vertically (in the Y direction) and replacing the node B with the node A. Since the layout of FIG. 6 is easily understandable from the description on the layout of FIG. 4, detailed description is omitted here.

The resistor elements RU are formed in the RMetal interconnect layer. Each two of the resistor elements RU are connected in series between the external output terminal PAD and the node A. The protective resistance Rsn is constituted by a plurality of such resistor elements RU.

As described above, according to this embodiment, the IO cell 10a includes the output circuit 11. The protective resistances Rsp and Rsn of the output circuit 11 are each constituted by a plurality of resistor elements RU extending in the X direction formed in the RMetal interconnect layer that is formed in the BEOL. In the M2 interconnect layer located below the RMetal interconnect layer, the M2 interconnects 41, 42, 43, 44, and 45, which are power supply lines or signal lines, extend in the X direction and are placed adjacent to one another in the Y direction. Here, the M2 interconnects 41, 42, 43, 44, and 45 are placed not to overlap any resistor elements RU in planar view, and the resistor elements RU are placed between any two adjacent interconnects of the M2 interconnects 41, 42, 43, 44, and 45. With this placement, since the M2 interconnects 41, 42, 43, 44, and 45 are placed at positions avoiding the resistor elements RU in planar view, the parasitic capacitance between these interconnects and the resistor elements RU is kept small. Therefore, the parasitic capacitance related to the resistor elements RU can be reduced.

Also, in the M5 interconnect layer located above the RMetal interconnect layer, the M5 interconnects 21, 22, and 23 extend in the Y direction and are placed adjacent to one another in the X direction. Here, the M5 interconnects 21, 22, and 23 are placed not to overlap any resistor elements RU in planar view, and the resistor elements RU are placed between any two adjacent interconnects of the M5 interconnects 21, 22, and 23. With this placement, since the M5 interconnects 21, 22, and 23 are placed at positions avoiding the resistor elements RU in planar view, the parasitic capacitance between these interconnects and the resistor elements RU is kept small. Therefore, the parasitic capacitance related to the resistor elements RU can be reduced.

While the power supply lines 71, 72, 73, and 74 extending in the Y direction are formed in the M3 interconnect layer in this embodiment, the power supply lines may be formed in an interconnect layer other than the M3 interconnect layer, such as the M5 interconnect layer. Also, the power supply lines may be formed in a plurality of interconnect layers. In these cases, also, the power supply lines should preferably be placed not to overlap any resistor elements RU in planar view.

In the M2 interconnect layer and the M5 interconnect layer, dummy metal interconnects may be placed at positions overlapping the resistor elements RU in planar view. With this, flattening of the interconnect layers, improvement in reliability, and improvement in yield can be achieved. That is, according to the present disclosure, in the M2 and M5 interconnect layers, a dummy metal interconnect may be placed between each two adjacent interconnects that are each a power supply line or a signal line so as to overlap resistor elements RU.

### Second Embodiment

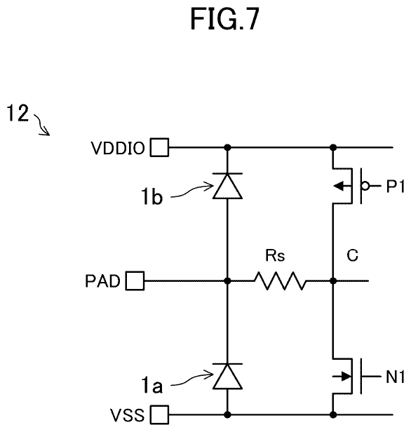

FIG. 7 is a circuit configuration diagram of an output circuit 12 according to this embodiment. The circuit configuration of FIG. 7 is similar to the circuit configuration of FIG. 2 in the first embodiment, except for the position of insertion of a protective resistance. That is, in the output circuit 12 of FIG. 7, a protective resistance Rs is provided in place of the protective resistances Rsn and Rsp in FIG. 2. In FIG. 7, the drains of the output transistors P1 and N1 are mutually connected, and the protective resistance Rs is provided between the external output terminal PAD and the drains of the output transistors P1 and N1. Note that the node between the drains of the output transistors P1 and N1 and the protective resistance Rs is herein called node C.

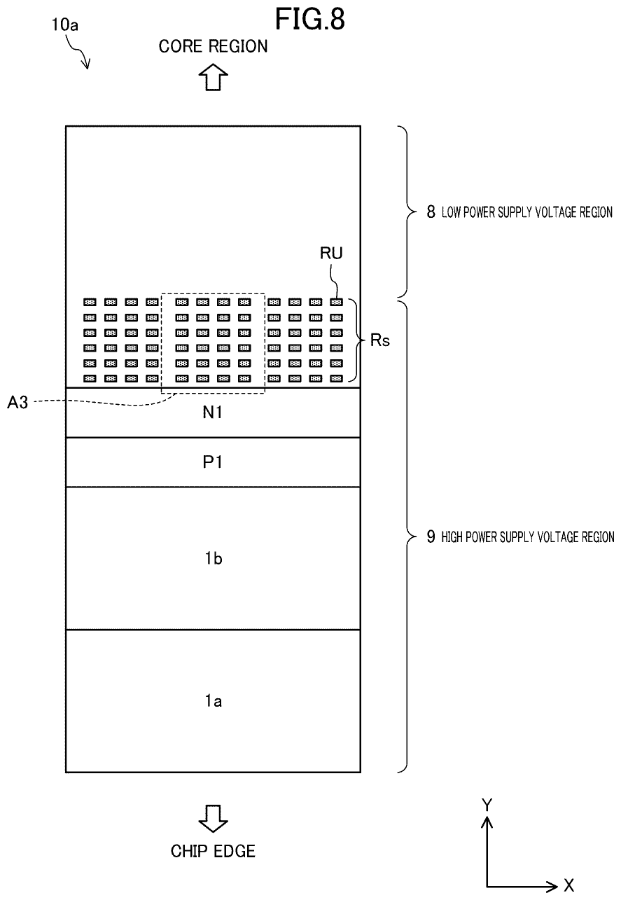

FIG. 8 shows an overview example of the layout of an IO cell. The layout of FIG. 8 corresponds to the IO cell 10a, one of the IO cells 10 arranged along the lower edge of the semiconductor integrated circuit device 1 in FIG. 1. In the IO cell layout of FIG. 8, the placement of the high power supply voltage region and the low power supply voltage region is different from that in the IO cell layout of FIG. 3. The IO cell 10a of FIG. 8 has a low power supply voltage region 8 and a high power supply voltage region 9 separated from each other in the Y direction. The low power supply voltage region 8 is located closer to the core region 2 and the high power supply voltage region 9 is located closer to the chip edge.

The IO cell 10a shown in FIG. 8 constitutes the output circuit 12 of FIG. 7. In the high power supply voltage region 9, the ESD protection diode 1a, the ESD protection diode 1b, the output transistor P1, and the output transistor N1 are placed in this order from the chip edge. In the high power supply voltage region 9, resistor elements RU are arranged in an array in the X and Y directions above a sector other than the sectors where the ESD protection diode 1a, the ESD protection diode 1b, the output transistor P1, and the output transistor N1 are placed. The resistor elements RU are mutually connected to constitute the protective resistance Rs. By placing the protective resistance Rs above a sector where devices such as transistors constituting another circuit are placed, the area of the IO cell 10a can be reduced.

The connecting style of the resistor elements RU may be serial connection, parallel connection, or a combination of serial connection and parallel connection. Also, some of the resistor elements RU constituting the protective resistance Rs may lie over the low power supply voltage region 8.

The order of the placement of the ESD protection diode 1a, the ESD protection diode 1b, the output transistor P1, and the output transistor N1 is not limited to that shown in FIG. 8. For example, the positions of the output transistor P1 and the output transistor N1 may be changed with each other, and the positions of the ESD protection diode 1a and the ESD protection diode 1b may be changed with each other.

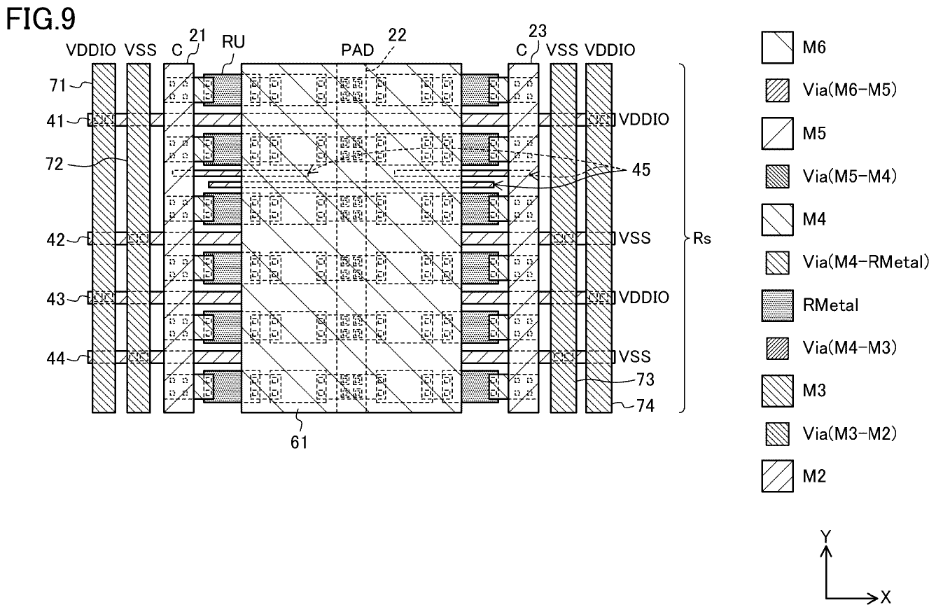

FIG. 9 is a plan view showing details of the layout of an IO cell, which shows the structure of M2 to M6 interconnect layers in part A3 in FIG. 8. Note that the cross-sectional structure is similar to that in the first embodiment and therefore illustration is omitted here.

The layout of FIG. 9 is similar to the layout of FIG. 4 in the first embodiment, except that the M5 interconnects 21 and 23 correspond to the node C, not the node B.

The resistor elements RU are formed in the RMetal interconnect layer. Each two of the resistor elements RU are connected in series between the external output terminal PAD and the node C. That is, the resistor elements RU are connected between the external output terminal PAD and the node C through a route of M6 interconnect 61 (PAD)→via (M6-M5)→M5 interconnect 22→via (M5-M4)→M4 interconnect→via (M4-RMetal)→resistor element RU→via (M4-RMetal)→M4 interconnect→via (M4-RMetal)→resistor element RU→via (M4-RMetal)→M4 interconnect→via (M5-M4)→M5 interconnect 21 (node C). Similarly, resistor elements RU are connected between the M6 interconnect 61 (PAD) and the M5 interconnect 23 (node C). The protective resistance Rs is constituted by a plurality of such resistor elements RU.

In FIG. 9, as in FIG. 4, none of the M2 interconnects 41, 42, 43, 44, and 45 that are power supply lines or signal lines in the M2 interconnect layer overlap any of the resistor elements RU in planar view. For example, the M2 interconnects 42 and 43 that are power supply lines are placed adjacent to each other in the Y direction. The M2 interconnects 42 and 43 do not overlap any resistor elements RU in planar view, and resistor elements RU are placed between these interconnects. That is, the M2 interconnects 42 and 43 are placed to sandwich the resistor elements RU in planar view. Also, the M2 interconnect 41 that is a power supply line and the M2 interconnects 45 that are signal lines are placed adjacent to each other in the Y direction. The M2 interconnects 41 and 45 do not overlap any resistor elements RU in planar view, and resistor elements RU are placed between these interconnects. In other words, the power supply lines and the signal lines in the M2 interconnect layer are placed at positions avoiding the resistor elements RU in planar view. With this, the parasitic capacitance related to the resistor elements RU is reduced.

Also, none of the M5 interconnects 21, 22, and 23 in the M5 interconnect layer overlap any resistor elements RU in planar view. For example, the M5 interconnect 21 corresponding to the node C and the M5 interconnect 22 corresponding to the external output terminal PAD are placed adjacent to each other in the X direction. The M5 interconnects 21 and 22 do not overlap any resistor elements RU in planar view, and resistor elements RU are placed between these interconnects. That is, the M5 interconnects 21 and 22 are placed to sandwich the resistor elements RU in planar view. With this, the parasitic capacitance related to the resistor elements RU is reduced. Note that the M5 interconnect 22 corresponding to the external output terminal PAD is allowed to overlap resistor elements RU in planar view. As described above, according to this embodiment, similar effects to those in the first embodiment can be obtained. That is, since the M2 interconnects 41, 42, 43, 44, and 45 are placed at positions avoiding the resistor elements RU in planar view, the parasitic capacitance between these interconnects and the resistor elements RU is kept small. Therefore, the parasitic capacitance related to the resistor elements RU can be reduced. Also, since the M5 interconnects 21, 22, and 23 are placed at positions avoiding the resistor elements RU in planar view, the parasitic capacitance between these interconnects and the resistor elements RU is kept small. Therefore, the parasitic capacitance related to the resistor elements RU can be reduced.

### Alteration of Second Embodiment

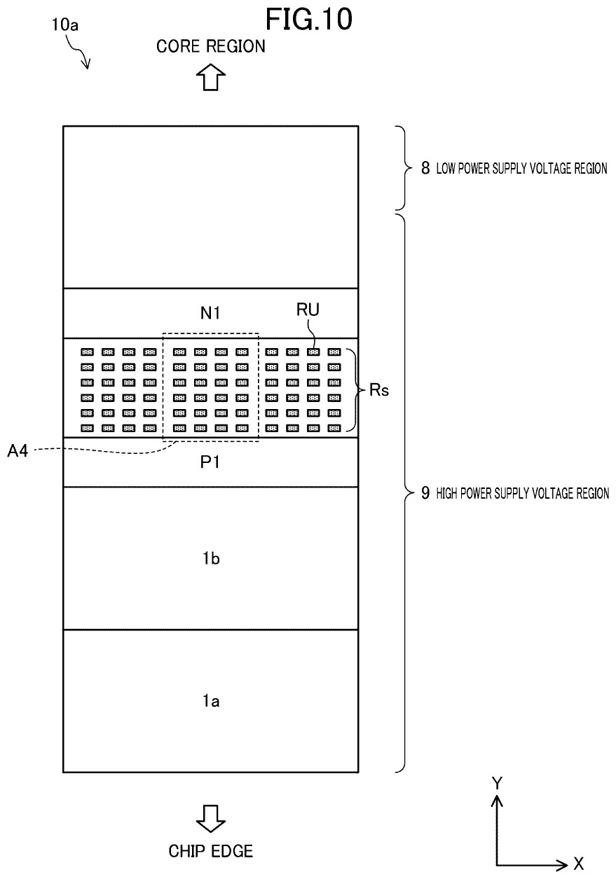

FIG. 10 shows an overview of the IO cell layout in an alteration of the second embodiment. In the layout of FIG. 10, in comparison with the layout of FIG. 8, the position of the output transistor N1 is shifted to an upper part in the figure. The protective resistance Rs is placed above a sector between the output transistor N1 and the output transistor P1.

The structure of the M2 to M6 interconnect layers in part A4 in FIG. 10 is similar to that in FIG. 9, and therefore illustration is omitted here.

According to this alteration, similar effects to those in the above embodiment are obtained. In this alteration, also, the following effect is obtained in addition to the effects in the second embodiment. Since the output transistor N1 and the output transistor P1 are placed on the opposite sides of the protective resistance Rs, the length of interconnects between the protective resistance Rs and the output transistor N1 and the length of interconnects between the protective resistance Rs and the output transistor P1 can be made roughly equal to each other. This can improve the unbalancing in interconnect parasitic components.

While the p-type transistor and the n-type transistor are both single-stage transistors in the output circuit in the above embodiments, the configuration is not limited to this. For example, they may be plural-stage transistors, such as two-or three-stage transistors, connected in series. Also, in the above embodiments, the output circuit may be an input/output circuit including an input circuit.

While the RMetal interconnect layer is formed between the M4 interconnect layer and the M3 interconnect layer in the above embodiments, the configuration is not limited to this. Any RMetal interconnect layer is acceptable as long as it is formed in the BEOL.

According to the present disclosure, in a semiconductor integrated circuit device using resistor elements formed in the BEOL, the parasitic capacitance related to the resistor elements can be reduced. The present disclosure is therefore useful for improving the performance of system LSI, for example.

1. A semiconductor integrated circuit device comprising a plurality of IO cells arranged in a first direction,
wherein
at least one of the plurality of IO cells includes an output circuit,
the output circuit includes
an external output terminal, and
a protective resistance constituted by a plurality of resistor elements formed in a first interconnect layer, the first interconnect layer being formed in an interconnect process (back end of line (BEOL)), one of ends of the protective resistance being connected to the external output terminal,
the plurality of resistor elements of the protective resistance extend in the first direction and are connected to interconnects formed in a second interconnect layer through vias,
in a third interconnect layer located below the first interconnect layer, first and second interconnects that are each a power supply line or a signal line extend in the first direction and are placed adjacent to each other in a second direction perpendicular to the first direction, and
the first and second interconnects are placed at positions having no overlap with any of the plurality of resistor elements in planar view, and at least one of the plurality of resistor elements is placed between the first interconnect and the second interconnect.

2. The semiconductor integrated circuit device of claim 1, wherein
in a fourth interconnect layer located above the first interconnect layer, third and fourth interconnects that are each a power supply line or a signal line extend in the second direction and are placed adjacent to each other in the first direction, and
the third and fourth interconnects are placed at positions having no overlap with any of the plurality of resistor elements in planar view, and at least one of the plurality of resistor elements is placed between the third interconnect and the fourth interconnect.

3. The semiconductor integrated circuit device of claim 1, wherein
the plurality of resistor elements of the protective resistance include two or more resistor elements connected in series to the external output terminal.

4. The semiconductor integrated circuit device of claim 1, wherein
the plurality of resistor elements of the protective resistance are arranged in an array in the first direction and the second direction in the first interconnect layer.
